(19) United States
(12) Patent Application Publication
(10) Pub. No.: US 2025/0062271 A1
(43) Pub. Date: Feb. 20, 2025

(54) SEMICONDUCTOR MODULE AND METHOD FOR MANUFACTURING SEMICONDUCTOR MODULE

(71) Applicant: FUJI ELECTRIC CO., LTD., Kawasaki-shi (JP)

(72) Inventors: Yoko NAKAMURA, Kawasaki-shi (JP); Akihiko IWAYA, Kawasaki-shi (JP); Mai SAITO, Kawasaki-shi (JP); Tsubasa WATAKABE, Kawasaki-shi (JP)

(73) Assignee: FUJI ELECTRIC CO., LTD., Kawasaki-shi (JP)

(21) Appl. No.: 18/933,990

(22) Filed: Oct. 31, 2024

Related U.S. Application Data
(63) Continuation of application No. PCT/JP2023/036710, filed on Oct. 10, 2023.

(30) Foreign Application Priority Data
Nov. 4, 2022 (JP) 2022-177078

(51) Int. Cl. H01L 23/00; H01L 23/373; H01L 25/07

(52) U.S. Cl. CPC H01L 24/40; H01L 23/3735; H01L 24/32; H01L 24/35; H01L 24/73; H01L 25/072; H01L 2224/32225; H01L 2224/352; H01L 2224/4005; H01L 2224/40225; H01L 2224/73263; H01L 2924/13055; H01L 2924/35121

(57) ABSTRACT

A semiconductor module, including: a stacked substrate including a plurality of circuit boards formed on an upper surface of an insulating plate; a semiconductor element formed on an upper surface of one of the plurality of circuit boards; and a metal wiring board formed on an upper surface of the semiconductor element. The metal wiring board has a bonding portion bonded to the upper surface of the semiconductor element via a bonding material. The bonding portion includes a plate-shaped portion having an upper surface and a lower surface. The plate-shaped portion has a roughened region in which a plurality of recessed portions are formed on the upper surface of the plate-shaped portion. The plurality of recessed portions include a plurality of first recessed portions that each has a peeling suppressing portion protruding inward to thereby narrow a width of each first recessed portion.

### CROSS-REFERENCE TO RELATED APPLICATION

This application is a continuation application of International Patent application PCT/JP2023/036710, filed on Oct. 10, 2023, which claims priority to Japanese patent application No. JP 2022-177078, filed on Nov. 4, 2022, the contents of which are incorporated by reference herein in their entirety.

### TECHNICAL FIELD

The present invention relates to a semiconductor module and a method for manufacturing the semiconductor module.

### BACKGROUND ART

A semiconductor module has a substrate, on which a semiconductor element such as an insulated gate bipolar transistor (IGBT), a power metal oxide semiconductor field effect transistor (MOSFET), or a free wheeling diode (FWD) is provided, and is used in an inverter device and the like.

In this type of semiconductor module, a semiconductor element is arranged on an insulating substrate (which may be referred to as a stacked substrate), and a metal wiring board for wiring (which may be referred to as a lead frame) is arranged on an upper surface electrode of the semiconductor element in, for example, Patent Literatures 1 to 3. The metal wiring board is formed into a predetermined shape by, for example, pressing a metal plate. One end of the metal wiring board is electrically bonded to the upper surface electrode with a bonding material such as solder.

In the semiconductor module, a sealing resin is filled in a case member, and an internal structure including the metal wiring board is covered with the sealing resin. In order to improve the adhesion strength of the sealing resin to the metal wiring board, Patent Literature 4 describes that a dovetail-shaped groove having a narrower open portion than the width of a bottom portion is formed in the metal wiring board, and Patent Literature 5 describes that a plurality of lattice-shaped grooves are formed in the metal wiring board.

Patent Literatures 6 to 9 describe that a plurality of dimples are formed on a surface of the metal wiring board and protrusions (bending portions, turnover portions, hook portions) are provided on inner walls of the dimples to improve the adhesion strength of the sealing resin. As a method of forming the dimples, holes are formed by the first pressing, and some of the holes are deformed to form the protrusions on the inner walls by performing the second pressing on peripheries of the holes.

### CITATION LIST

### Patent Literature

Patent Literature 1: JP 2018-088448 A
Patent Literature 2: JP 2016-139635 A
Patent Literature 3: JP 2015-176871 A
Patent Literature 4: JP 6-163773 A
Patent Literature 5: JP 2021-077718 A
Patent Literature 6: JP 7-273270 A
Patent Literature 7: JP 2005-191178 A
Patent Literature 8: JP 2017-005124 A
Patent Literature 9: JP 2007-258587 A

### SUMMARY OF INVENTION

### Technical Problem

In this type of semiconductor module, the power semiconductor element generates heat following a switching operation. In the structure in which the metal wiring board is solder-bonded to the surface of the power semiconductor element as described above, distortion may occur in the bonding portion due to a fluctuation of internal stress generated with temperature change. As a result, a decrease in the adhesion of the sealing resin to the bonding portion of the metal wiring board is assumed.

The present invention has been made in view of such a point, and an object of the present invention is to provide a semiconductor module capable of improving adhesion between a bonding portion of a metal wiring board and a sealing resin.

### Solution to Problem

A semiconductor module according to one aspect of the present invention includes: a stacked substrate in which a plurality of circuit boards are arranged on an upper surface of an insulating plate; a semiconductor element arranged on an upper surface of at least one of the circuit boards; and a metal wiring board arranged on an upper surface of the semiconductor element, in which the metal wiring board has a bonding portion bonded to the upper surface of the semiconductor element via a bonding material, the bonding portion includes a plate-shaped portion having an upper surface and a lower surface, the plate-shaped portion includes a plurality of roughened recessed portions that roughen the upper surface, and at least some of the plurality of roughened recessed portions include a peeling suppressing portion that protrudes inward and narrows an open width.

### Advantageous Effects of Invention

According to the present invention, adhesion between a bonding portion of a metal wiring board and a sealing resin in a semiconductor module can be improved.

### BRIEF DESCRIPTION OF DRAWINGS

FIG. 1 is a schematic view of a semiconductor device according to a present embodiment as viewed from above.

FIG. 2 is a cross-sectional view of the semiconductor device illustrated in FIG. 1 taken along line A-A.

FIG. 3 is an enlarged view of a metal wiring board according to the present embodiment.

FIG. 4 is a plan view of the metal wiring board illustrated in FIG. 3 as viewed in a direction of arrow B.

FIG. 5 is an enlarged view of a portion C of the metal wiring board illustrated in FIG. 3.

FIG. 6 is a plan view illustrating a specific example of a semiconductor module to which the metal wiring board according to the present embodiment is applied.

FIG. 7 is an equivalent circuit diagram of the semiconductor device according to the present embodiment.

FIG. 8 is a plan view illustrating a configuration of roughened recessed portions according to a first embodiment in a region portion of D in FIG. 4.

FIG. 9 is a cross-sectional view taken along line E-E of FIG. 8.

FIG. 10 is a plan view illustrating a configuration of roughened recessed portions according to a second embodiment in the region portion of D in FIG. 4.

FIG. 11 is a plan view illustrating a configuration of roughened recessed portions according to a third embodiment in the region portion of D in FIG. 4.

FIG. 12 is a plan view illustrating a configuration of roughened recessed portions according to a fourth embodiment in the region portion of D in FIG. 5.

FIG. 13 is a plan view illustrating a configuration of roughened recessed portions according to a fifth embodiment in the region portion of D in FIG. 4.

FIGS. 14A to 14C are diagrams illustrating an example of a manufacturing method for forming roughened recessed portions including a peeling suppressing portion.

### DESCRIPTION OF EMBODIMENTS

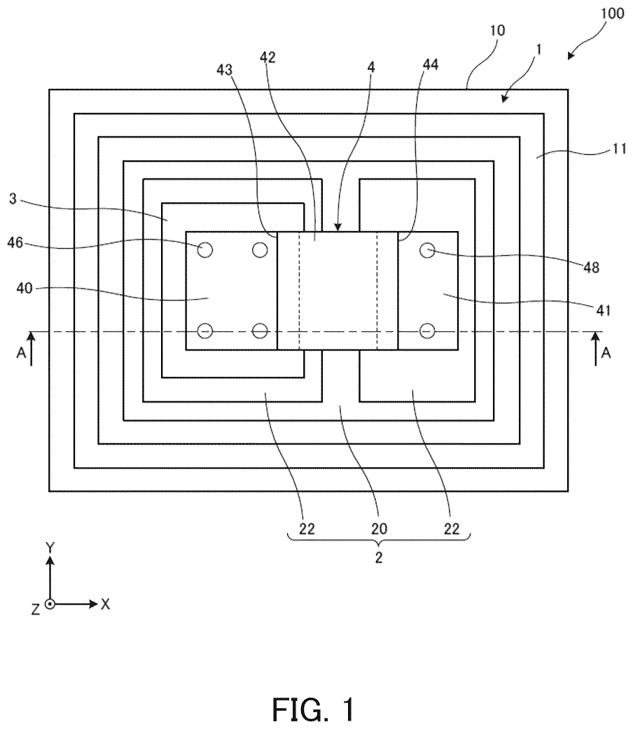

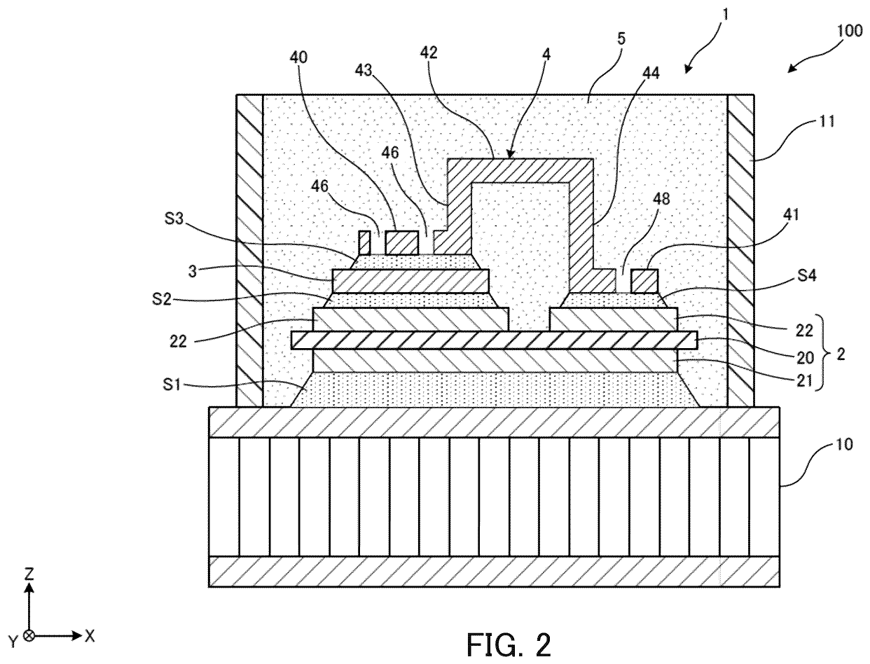

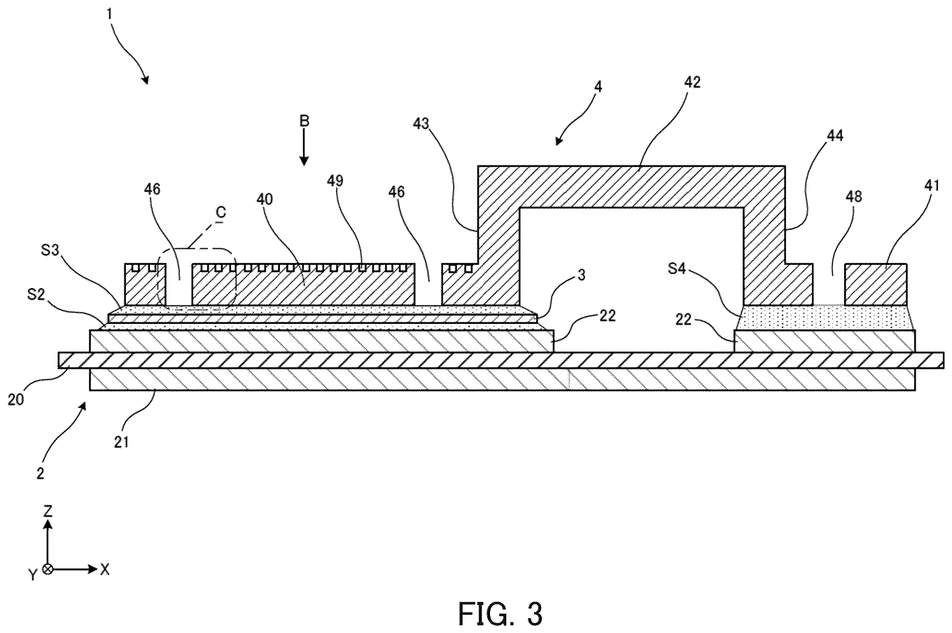

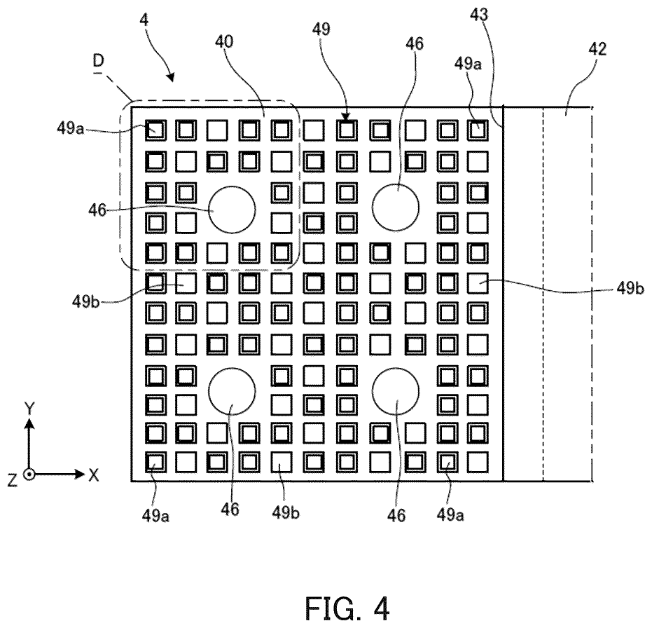

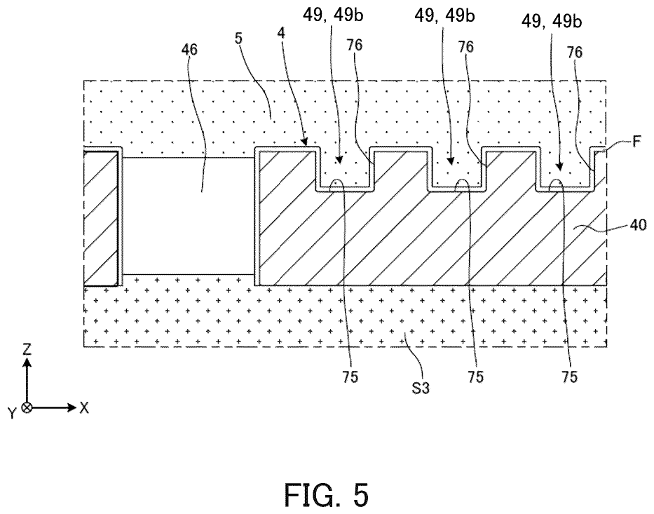

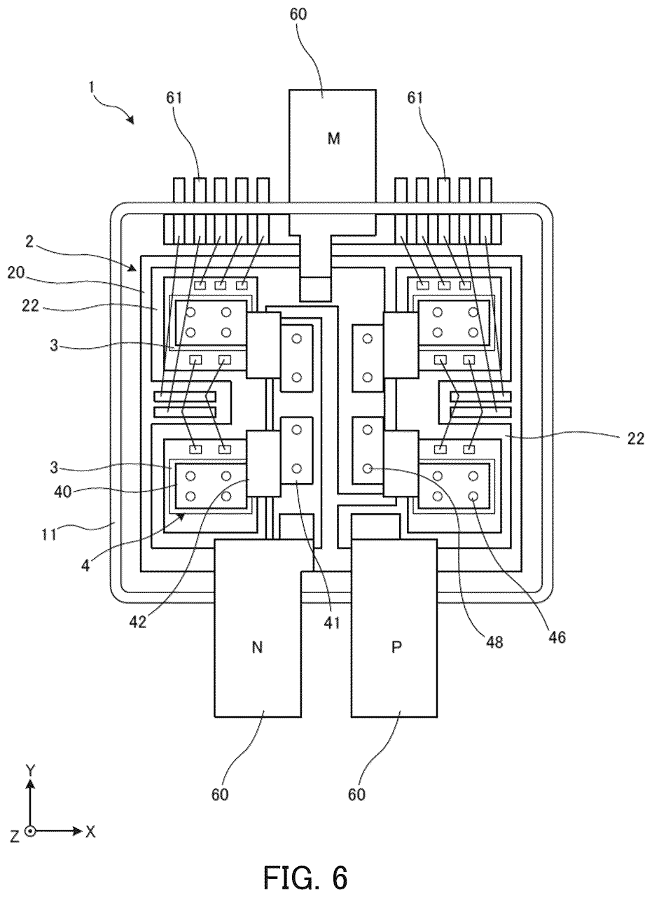

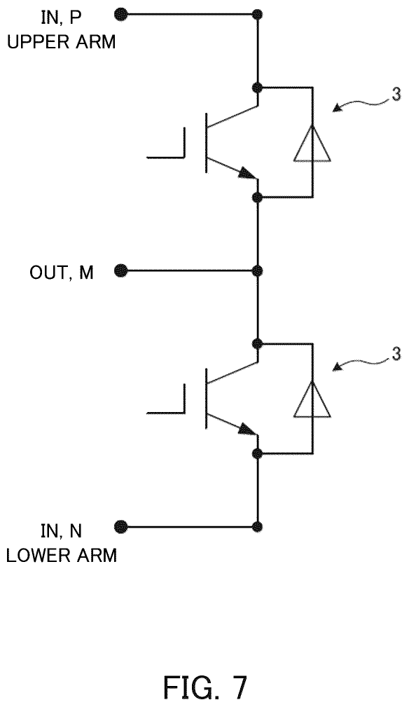

Hereinafter, a semiconductor module and a semiconductor device to which the present invention can be applied will be described. First, referring to FIGS. 1 to 7, an overall configuration of a semiconductor module and a semiconductor device and the summary of a metal wiring board including the semiconductor module and the semiconductor device will be described. FIG. 1 is a schematic view of a semiconductor device according to a present embodiment as viewed from above. FIG. 2 is a cross-sectional view of the semiconductor device illustrated in FIG. 1 taken along line A-A. FIG. 3 is an enlarged view of a metal wiring board according to the present embodiment. FIG. 4 is a plan view of the metal wiring board illustrated in FIG. 3 as viewed in a direction of arrow B. FIG. 5 is an enlarged view of a portion C of the metal wiring board illustrated in FIG. 3. FIG. 6 is a plan view illustrating a specific example of a semiconductor module to which the metal wiring board according to the present embodiment is applied. FIG. 7 is an equivalent circuit diagram of the semiconductor device according to the present embodiment. Here, the configuration is such that anti-parallel circuits of an IGBT and an FWD are connected in series as a semiconductor element 3.

In the following drawings, a longitudinal direction of the semiconductor module (a cooler) is defined as an X direction, a lateral direction of the semiconductor module (the cooler) is defined as a Y direction, and a height direction (a direction of the thickness of the substrate) is defined as a Z direction. The longitudinal direction of the semiconductor module indicates a direction in which the plurality of circuit boards are arrayed. X, Y, and Z axes illustrated are orthogonal to each other and form a right-handed system. In some cases, the X direction may be referred to as a left-right direction, the Y direction may be referred to as a front-rear direction, and the Z direction may be referred to as an up-down direction. These directions (front-rear, left-right, and up-down directions) are terms used for convenience of description, and a correspondence relationship with the XYZ directions, respectively, may change depending on an attachment posture of the semiconductor module. For example, a heat dissipation surface side (cooler side) of the semiconductor module is referred to as a lower surface side, and the opposite side is referred to as an upper surface side. Also, in the present specification, the term “in plan view” means a case where an upper surface or a lower surface of the semiconductor module is viewed in the Z direction. In addition, the ratio between the width and the thickness and the size relationship between the members in the drawings are illustrated in schematic views, and thus are not necessarily the same among the drawings. For convenience of description, it is also assumed that the size relationship between the members may be exaggerated.

A semiconductor device 100 according to the present embodiment is applied to, for example, a power conversion device such as an inverter of an industrial or in-vehicle motor. As illustrated in FIGS. 1 and 2, the semiconductor device 100 is configured by arranging a semiconductor module 1 on an upper surface of a cooler 10. Note that the cooler 10 has any configuration with respect to the semiconductor module 1.

The cooler 10 releases heat of the semiconductor module 1 to the outside, and has a rectangular parallelepiped shape as a whole. Although not particularly illustrated, the cooler 10 is configured by providing a plurality of fins on a lower surface side of a base plate and housing these fins in a water jacket. Note that the cooler 10 is not limited thereto and can be appropriately changed.

The semiconductor module 1 is configured by arranging a stacked substrate 2, the semiconductor element 3, a metal wiring board 4, and the like in a case 11.

The stacked substrate 2 is composed of, for example, a direct copper bonding (DCB) substrate, an active metal brazing (AMB) substrate, or a metal base substrate. The stacked substrate 2 is configured by stacking an insulating plate 20, a heat dissipation plate 21, and a plurality of circuit boards 22, and is formed into a rectangular shape as a whole in plan view.

Specifically, the insulating plate 20 is formed from a plate-shaped body having an upper surface and a lower surface, and has a rectangular shape elongated in the X direction in plan view. The insulating plate 20 may be formed from, for example, a ceramic material such as aluminum oxide (Al₂O₃), aluminum nitride (AlN), silicon nitride (Si₃N₄), and aluminum oxide (Al₂O₃) and zirconium oxide (ZrO₂).

In addition, the insulating plate 20 may be formed from, for example, a thermosetting resin such as an epoxy resin or a polyimide resin, or a composite material using glass or a ceramic material as a filler in the thermosetting resin. The insulating plate 20 preferably has flexibility and may be formed from, for example, a material containing a thermosetting resin. Further, the insulating plate 20 may be referred to as an insulating layer or an insulating film.

The heat dissipation plate 21 has a predetermined thickness in the Z direction and has a rectangular shape elongated in the Y direction in plan view. The heat dissipation plate 21 is formed from, for example, a metal plate having good thermal conductivity such as copper or aluminum. The heat dissipation plate 21 is arranged on a lower surface of the insulating plate 20. The lower surface of the heat dissipation plate 21 is a surface to be attached to the cooler 10, a device to which the semiconductor module 1 is attached, and also functions as a heat dissipation surface (heat dissipation region) for releasing heat of the semiconductor module 1. The heat dissipation plate 21 is bonded to the upper surface of the cooler 10 via a bonding material S1 such as solder. The heat dissipation plate 21 may be arranged on the upper surface of the cooler 10 with a thermal conductive material, such as thermal grease or thermal compound, interposed therebetween.

Each of the plurality of circuit boards 22 has a predetermined thickness and is arranged on the upper surface of the insulating plate 20. Each of the circuit boards 22 is formed into an electrically independent island shape. For example, the circuit board 22 has a rectangular shape in plan view, and is arranged side by side in the X direction on the insulating plate 20. Note that the number of the circuit boards 22 is not limited to two as illustrated in FIG. 1, and can be changed as appropriate. As illustrated in FIG. 6, three or more circuit boards 22 may be arranged on the insulating plate 20. In addition, the shape, arrangement location, and the like of the circuit board 22 are not limited thereto and can be changed as appropriate. These circuit boards 22 are formed from, for example, a metal plate having good thermal conductivity such as copper or aluminum. The circuit board 22 may be referred to as a circuit layer or a circuit pattern.

The semiconductor element 3 is arranged on an upper surface of the predetermined circuit board 22 (circuit board 22 on the negative side in the X direction) via a bonding material S2 such as solder. The semiconductor element 3 is formed from a semiconductor substrate such as silicon (Si) or silicon carbide (SiC) in a rectangular shape in plan view. The semiconductor element 3 may be a power semiconductor element. For the semiconductor element 3, a switching element such as an insulated gate bipolar transistor (IGBT) and a power metal oxide semiconductor field effect transistor (power MOSFET), and a diode such as a free wheeling diode (FWD) are used.

In the present embodiment, the semiconductor element 3 includes, for example, a reverse conducting (RC)-insulated gate bipolar transistor (IGBT) element in which the functions of an IGBT element and a free wheeling diode (FWD) element are integrated.

Note that the semiconductor element 3 is not limited thereto, and may be configured by combining the above-described switching element, diode, and the like. For example, the IGBT element and the FWD element may be configured separately. Also, a reverse blocking (RB)-IGBT or the like having a sufficient withstand voltage against a reverse bias may be used as the semiconductor element 3. In addition, the shape, number, arrangement location, and the like of the semiconductor element 3 can appropriately be changed.

In addition, electrodes (not illustrated) are formed on an upper surface and a lower surface of the semiconductor element 3, respectively. For example, the electrode on the upper surface side (upper surface electrode) is configured as an emitter electrode (source electrode) or a gate electrode, and the electrode on the lower surface side (lower surface electrode) is configured as a collector electrode (drain electrode).

Note that the semiconductor element 3 in the present embodiment is a so-called vertical switching element in which the functional element as described above is formed on a semiconductor substrate, but is not limited thereto, and may be a horizontal switching element.

The metal wiring board 4 is arranged on the upper surface of the semiconductor element 3. The metal wiring board 4 is configured as a plate-shaped body having an upper surface and a lower surface, and is formed from, for example, a metal material such as a copper material, a copper alloy-based material, an aluminum alloy-based material, or an iron alloy-based material. The metal wiring board 4 is formed into a predetermined shape by, for example, pressing. Note that the shape of the metal wiring board 4 described below is merely an example, and can be changed as appropriate. In addition, the metal wiring board may be referred to as a lead frame.

The metal wiring board 4 according to the present embodiment is an elongated body extending in the X direction so as to straddle the plurality of circuit boards 22 in plan view, and has a crank shape that is bent a plurality of times in side view. Specifically, as illustrated in FIGS. 2 and 3, the metal wiring board 4 is configured by including a first bonding portion 40 bonded to the upper surface (the upper surface electrode) of the semiconductor element 3 via a bonding material S3 (a first bonding material), a second bonding portion 41 bonded to the upper surface of the circuit board 22 on the positive side in the X direction via a bonding material S4, and a connecting portion 42 connecting the first bonding portion 40 and the second bonding portion 41.

The width of the metal wiring board 4 in the Y direction is uniform from the first bonding portion 40 to the second bonding portion 41. In addition, the first bonding portion 40, the second bonding portion 41, and the connecting portion 42 are arranged in a line along the X direction in plan view. Note that the width of the metal wiring board 4 in the Y direction is not necessarily uniform from the first bonding portion 40 to the second bonding portion 41, and each portion may have a different width as illustrated in FIG. 6. In addition, the first bonding portion 40, the second bonding portion 41, and the connecting portion 42 are not necessarily arranged in a line, and may be arranged to be obliquely shifted from each other as illustrated in FIG. 6.

The first bonding portion 40 is formed into a rectangular shape smaller than the outer shape of the semiconductor element 3 in plan view, and includes a plate-shaped portion having an upper surface and a lower surface. A first bent portion 43 that is bent at a substantially right angle and rises upward is formed at an end portion of the first bonding portion 40 on the positive side in the X direction (the connecting portion 42 side). One end (the left end) of the connecting portion 42 is connected to the upper end of the first bent portion 43.

A plurality of through holes 46 are formed in the first bonding portion 40. Four through holes 46 in total including two through holes 46 in the X direction and two through holes 46 in the Y direction are provided. The four through holes 46 are arranged slightly inside of four corners of the first bonding portion 40. Each of the through holes 46 penetrates the first bonding portion 40 in the Z direction.

The second bonding portion 41 is formed into a rectangular shape smaller than the outer shape of the circuit board 22 in plan view, and includes a plate-shaped portion having an upper surface and a lower surface. A second bent portion 44 that is bent at a substantially right angle and rises upward is formed at an end portion of the second bonding portion 41 on the negative side in the X direction (the connecting portion 42 side). The other end (the right end) of the connecting portion 42 is connected to the upper end of the second bent portion 44.

A plurality of through holes 48 are formed in the second bonding portion 41. Two through holes 48 are provided at different positions in the Y direction. Each of the through holes 48 penetrates the second bonding portion 41 in the Z direction.

The connecting portion 42 extends in the horizontal direction, and as described above, one end thereof is connected to the first bent portion 43 and the other end thereof is connected to the second bent portion 44.

The length of the first bent portion 43 in the Z direction is shorter than that of the second bent portion 44 by the thickness of the semiconductor element 3. That is, the first bonding portion 40 and the second bonding portion 41 are provided at a position with different heights. More specifically, the first bonding portion 40 is provided at a position higher than the second bonding portion 41.

Note that the shape, number, arrangement location, and the like of the metal wiring board 4 described above are merely examples, and are not limited thereto and can be changed as appropriate. Although details will be described later, a plurality of (for example, four) metal wiring boards 4 may be arranged on one semiconductor module as illustrated in FIG. 6. Also, in the present embodiment, the semiconductor element 3 and the metal wiring board 4 described above, and a main terminal and the like to be described later form, for example, an inverter circuit illustrated in FIG. 7.

The periphery of the stacked substrate 2, the semiconductor element 3, and the metal wiring board 4 is surrounded by the case 11. The case 11 has a quadrangular annular tubular shape or a frame shape in plan view, and is formed from, for example, a synthetic resin. The case 11 may be formed from, for example, a thermosetting resin material such as an epoxy resin or silicone rubber. The lower end of the case 11 is adhered to the upper surface of the cooler 10 with an adhesive (not illustrated), and the upper end extends to a position sufficiently higher than the upper surface of the metal wiring board 4. Thus, the case 11 surrounds the periphery of the stacked substrate 2, the semiconductor element 3, and the metal wiring board 4, and defines a space for housing the stacked substrate 2, the semiconductor element 3, and the metal wiring board 4.

The internal space defined by the case 11 is filled with a sealing resin 5. The case 11 may be filled with the sealing resin 5 until its upper surface reaches the upper end of the case 11. Thus, the stacked substrate 2, the semiconductor element 3, and the metal wiring board 4 are sealed. The entire metal wiring board 4 is covered with the sealing resin 5.

The sealing resin 5 may be composed of, for example, a thermosetting resin. Preferably, the sealing resin 5 contains at least one of epoxy, silicone, urethane, polyimide, polyamide, and polyamide-imide. For example, an epoxy resin mixed with a filler is suitable for the sealing resin 5 from the viewpoint of insulation, heat resistance, and heat dissipation properties.

As in the specific example illustrated in FIG. 6, the case 11 may be provided with a plurality of main terminals 60 for main current and a plurality of control terminals 61 for control. The main terminal 60 is formed into a plate-shaped elongated body and is embedded in a side wall of the case 11. In FIG. 6, two main terminals 60 constituting an N terminal and a P terminal, respectively, are arranged side by side in the X direction on the side wall of the case 11 positioned on the negative side in the Y direction. In addition, a main terminal 60 constituting an M terminal is arranged on the side wall of the case 11 positioned on the positive side in the Y direction.

As described above, in the present embodiment, the semiconductor element 3, the metal wiring board 4, the main terminals 60, and the like form, for example, the inverter circuit illustrated in FIG. 7. These main terminals 60 (the N terminal, P terminal, M terminal) correspond to IN (N) (which may be referred to as a low potential-side input terminal or a negative electrode terminal), IN (P) (which may be referred to as a high potential-side input terminal or a positive electrode terminal), and OUT (M) (which may be referred to as an output terminal or an intermediate terminal) in FIG. 7, respectively.

In addition, the control terminal 61 is formed into a plate-shaped elongated body and is embedded in the side wall of the case 11 positioned on the positive side in the Y direction. The control terminal 61 is electrically connected to a predetermined control electrode of the semiconductor element 3 via a wiring member such as a bonding wire. These main terminal 60 and the control terminal 61 are formed from a metal material such as a copper material, a copper alloy-based material, an aluminum alloy-based material, or an iron alloy-based material, and have predetermined electrical conductivity and predetermined mechanical strength. The shapes, numbers, arrangement locations, and the like of the main terminal 60 and the control terminal 61 are not limited thereto, and can be changed as appropriate.

Incidentally, in the semiconductor module, it is desired to prevent the progress of peeling along the interface between the metal wiring board and the sealing resin. As a method for reducing peeling, it is conceivable, for example, to increase the surface area of the metal wiring board to improve adhesion (anchor effect) between the metal wiring board and the sealing resin. Examples of a method for increasing the surface area of the metal wiring board include forming an uneven shape on the surface of the metal wiring board. However, when the lower surface of the metal wiring board (the surface facing the semiconductor element) has an uneven shape, voids and sink marks are likely to occur in the bonding material. As a result, the mounting quality of the metal wiring board may be affected.

Also, examples of a method for roughening the surface of the metal wiring board include laser processing and a wet method using a chemical solution. However, these methods not only cause an increase in cost, but also may cause voids and sink marks in the bonding material due to a roughened lower surface side of the metal wiring board. That is, it is difficult to roughen the surface of the metal wiring board without affecting the quality of the bonding material immediately below the metal wiring board.

In the present embodiment, the plurality of through holes 46 are provided in the first bonding portion 40, and a plurality of roughened recessed portions 49 are provided on an upper surface (surface) of the first bonding portion 40. By forming the plurality of through holes 46, in a bonding step of the metal wiring board 4, while securing the thickness of the bonding material S3, the first bonding portion 40 can be prevented from being inclined with respect to the upper surface of the semiconductor element 3, and the posture of the metal wiring board 4 (first bonding portion 40) can be stabilized.

The through holes 48 formed in the second bonding portion 41 have the same effect as the through holes 46 of the first bonding portion 40. Accordingly, in the bonding step of the metal wiring board 4, while securing the thickness of the bonding material S4, the second bonding portion 41 can be prevented from being inclined with respect to the upper surface of the circuit board 22, and the posture of the metal wiring board 4 (second bonding portion 41) can be stabilized.

The through holes 46 and the through holes 48 have a cylindrical shape. Also, the shape of the through holes formed in the first bonding portion 40 and the second bonding portion 41 is not limited to a cylindrical shape.

In addition, the upper surface of the first bonding portion 40 is roughened by forming the plurality of roughened recessed portions 49. As a result, the surface area of the upper surface of the first bonding portion 40 increases, and the adhesion (anchor effect) between the upper surface of the first bonding portion 40 and the sealing resin 5 can be improved. In particular, it is preferable that the sealing resin 5 enters the roughened recessed portions 49. As a result, a further anchor effect can be expected. Accordingly, the progress of the peeling of the sealing resin 5 on the upper surface of the metal wiring board 4 due to thermal stress can be suppressed at a position above the semiconductor element 3.

The through holes 46 and the roughened recessed portions 49 in the first bonding portion 40 and the through holes 48 in the second bonding portion 41 are formed, for example, by pressing.

Note that the plurality of roughened recessed portions 49 may be formed on the upper surface of the second bonding portion 41, or may be formed only on the upper surface of the first bonding portion 40. That is, the roughened recessed portions 49 do not need to be formed in the connecting portion 42, the first bent portion 43, and the second bent portion 44 that constitute the portion other than the first bonding portion 40.

Since the semiconductor element 3 serving as a heat source is arranged immediately below the first bonding portion 40, it is possible to easily receive the influence of the anchor effect due to surface roughening. In addition, by roughening only the surface of the portion where the anchor effect is to be improved, it is not necessary to spend extra processing cost. That is, it can be said that the second bonding portion 41, the connecting portion 42, the first bent portion 43, and the second bent portion 44 have a smaller influence on the peeling of the sealing resin 5 than the first bonding portion 40. In this case, the surfaces of the second bonding portion 41, the connecting portion 42, the first bent portion 43, and the second bent portion 44 are flat, and the surface roughness thereof may be equivalent to the surface roughness of the lower surface of the first bonding portion 40.

In addition, the portion of the lower surface of the first bonding portion 40 excluding the through holes 46 is preferably a flat surface. That is, it is preferable that the roughened recessed portions 49 are not formed on the lower surface of the first bonding portion 40. For example, the surface roughness of the lower surface of the first bonding portion 40 is preferably smaller than the surface roughness of the upper surface of the first bonding portion 40. When the lower surface of the first bonding portion 40 is flat, voids and sink marks are unlikely to be generated in the bonding material S3.

In addition, as illustrated in FIG. 5, a coating film F may be interposed at the interface between the upper surface of the first bonding portion 40 and the sealing resin 5.

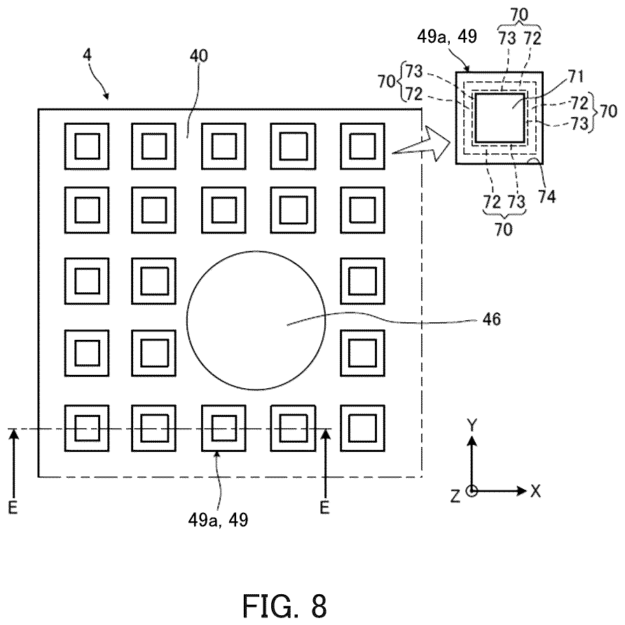

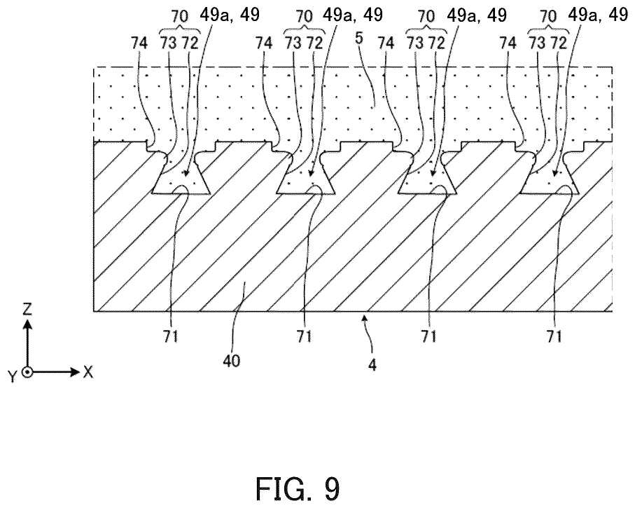

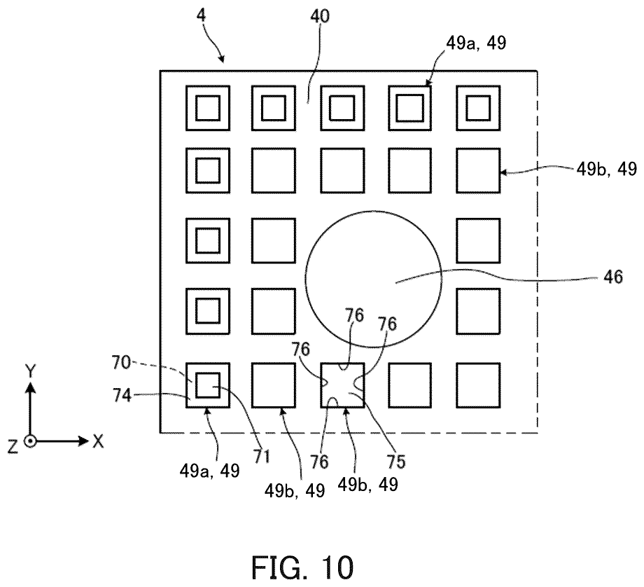

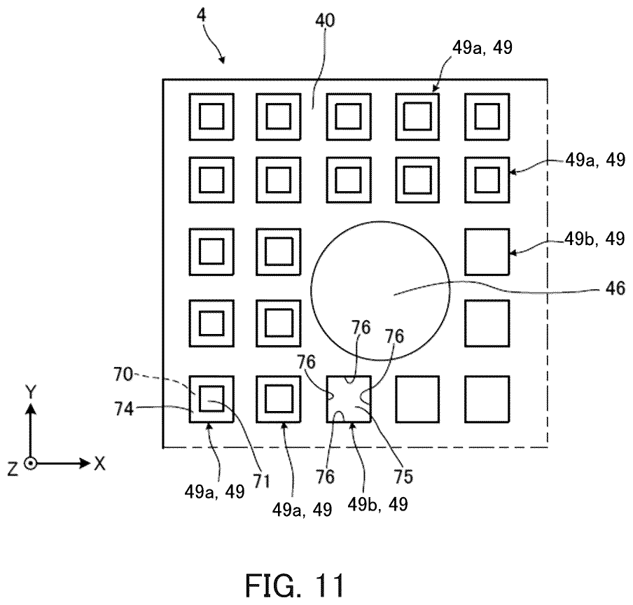

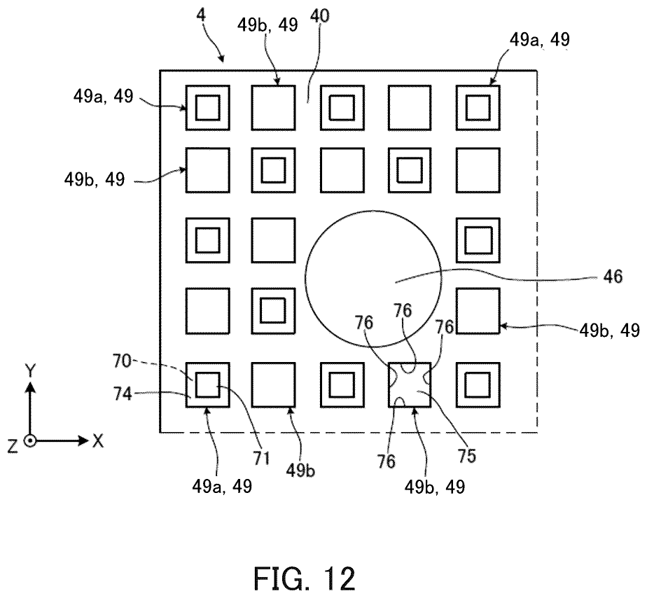

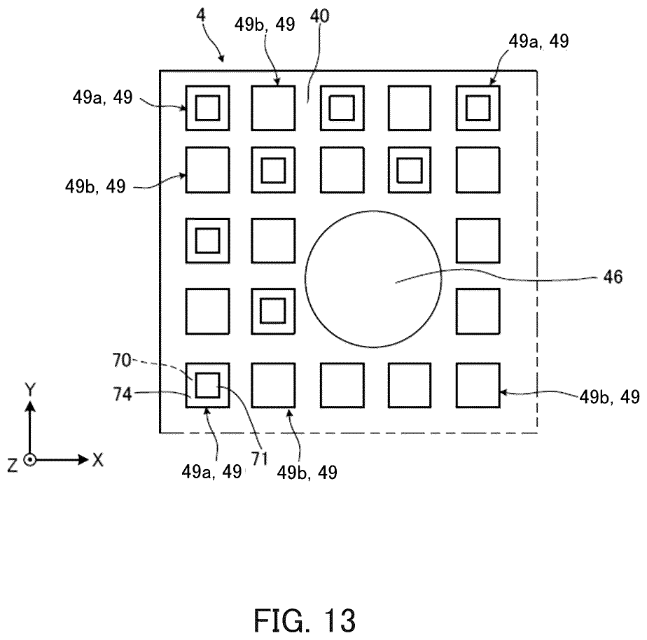

Next, referring to FIGS. 8 to 13, an embodiment having the configuration of the plurality of roughened recessed portions 49 provided on the upper surface of the first bonding portion 40 will be described. A region corresponding to a region portion of D surrounded by a dotted line in FIG. 4 is illustrated in FIGS. 8, 10, 11, 12, and 13. FIGS. 8 and 9 illustrate a first embodiment, FIG. 10 illustrates a second embodiment, FIG. 11 illustrates a third embodiment, FIG. 12 illustrates a fourth embodiment, and FIG. 13 illustrates a fifth embodiment. The upper surface of the first bonding portion 40 according to each of the embodiments includes a roughened region that is roughened by the plurality of roughened recessed portions 49 and a non-roughened region not including the roughened recessed portions 49, and the non-roughened region includes four through holes 46.

In each of the embodiments, a peeling suppressing portion 70 is provided in at least some of the plurality of roughened recessed portions 49. The peeling suppressing portion 70 is a portion that protrudes to the inside of the roughened recessed portion 49 and narrows an open width of the roughened recessed portion, and an effect of suppressing the peeling of the sealing resin 5 is obtained due to the configuration. In the following description, among the plurality of roughened recessed portions 49, the roughened recessed portion 49 including the peeling suppressing portion 70 is classified as a first roughened recessed portion 49a, and the roughened recessed portion 49 not including the peeling suppressing portion 70 is classified as a second roughened recessed portion 49b. Also, the arrangement of the first roughened recessed portions 49a and the second roughened recessed portions 49b illustrated in FIG. 4 are different from those of each of the embodiments illustrated in FIGS. 8 to 13, and the arrangement illustrated in FIG. 4 is also applicable thereto.

The first embodiment illustrated in FIGS. 8 and 9 is the example where a plurality of the first roughened recessed portions 49a including the peeling suppressing portion 70 are provided on the entire roughened region of the upper surface of the first bonding portion 40. In other words, in the first embodiment, the second roughened recessed portions 49b are not provided on the upper surface of the first bonding portion 40. The first roughened recessed portion 49a includes a bottom surface 71 having a rectangular shape in plan view, four inclined surfaces 72 extending upward from four sides of the bottom surface 71, and flange portions 73 protruding inward from the inclined surfaces 72 at upper ends of the inclined surfaces 72. In the first roughened recessed portion 49a, the open width is the minimum at the location of the flange portion 73, and increases from the flange portion 73 toward the bottom surface 71.

The flange portions 73 and the inclined surfaces 72 constitute the peeling suppressing portion 70. As illustrated in FIG. 9, the peeling suppressing portion 70 is a protrusion portion that protrudes toward the inside of the first roughened recessed portion 49a (the center side of the opening) further than the outer edge (four sides) of the bottom surface 71. An open recessed portion 74 having a square pillar shape is formed in an upper portion of the peeling suppressing portion 70, and is opened to the upper surface of the first bonding portion 40. A center portion of the bottom surface of the open recessed portion 74 communicates with the bottom side of the first roughened recessed portion 49a where the inclined surfaces 72 and the bottom surface 71 are present, and the periphery of the communication portion constitutes the flange portion 73. That is, the first roughened recessed portion 49a has a shape where the open width is narrowed at the location of the flange portion 73. In addition, an overhang structure where the interval of the four inclined surfaces 72 gradually decreases from the bottom surface 71 toward the flange portion 73 is adopted.

In the first roughened recessed portion 49a having the above-described configuration, the sealing resin 5 that penetrates into the inside below the open recessed portion 74 is not likely to come out to the open recessed portion 74 side due to the action of the flange portion 73 arranged to partially block the upper portion of the sealing resin 5 and the four inclined surfaces 72 formed below the flange portion 73. Accordingly, an effect of improving the adhesion between the first roughened recessed portion 49a and the sealing resin 5 is obtained. In particular, the configuration of FIG. 8 where all of the roughened recessed portions 49 in the roughened region are the first roughened recessed portions 49a can improve the adhesion with the sealing resin 5 as much as possible.

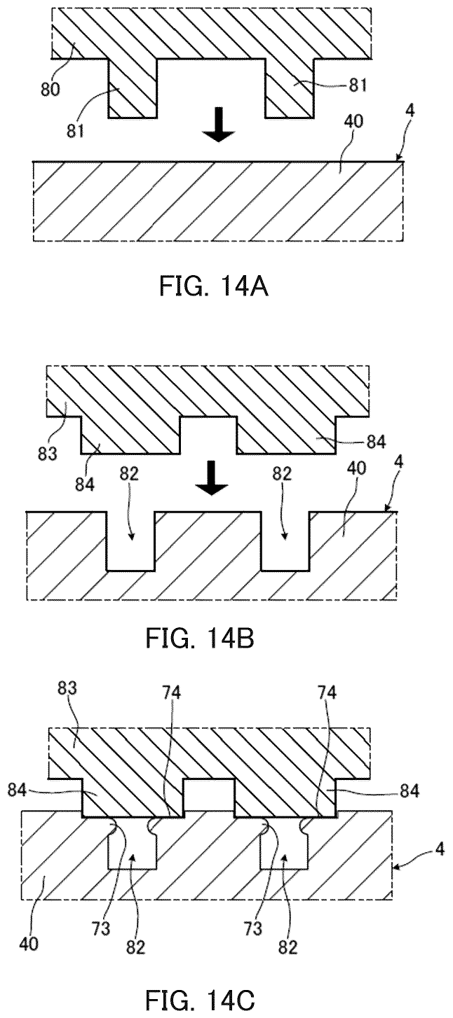

FIGS. 14A to 14C illustrate an example of a method for manufacturing the first roughened recessed portions 49a including the peeling suppressing portion 70. The first roughened recessed portions 49a are manufactured by pressing the metal plate as a precursor of the metal wiring board 4.

In a step of FIG. 14A, a first die 80 that is an upper die is pressed against the flat upper surface of the first bonding portion 40 for pressing. The first die 80 includes a plurality of press protrusions 81 having a square pillar shape, and each of the press protrusions 81 is pressed to form initial recessed portions 82 (refer to FIG. 14B) having a square pillar shape in the first bonding portion 40.

Next, in a step of FIG. 14B, a second die 83 that is an upper die is pressed against the first bonding portion 40 in a state where the plurality of initial recessed portions 82 are formed for pressing. The second die 83 includes a plurality of press protrusions 84 having a square pillar shape. Each of the press protrusions 84 is larger than the opening shape of four corners of each of the initial recessed portions 82. Then, the bottom surface of each of the press protrusions 84 abuts against the periphery of the opening of each of the initial recessed portions 82 from above.

As illustrated in a step of FIG. 14C, due to a force to press the second die 83, the open recessed portion 74 is formed at a location where each of the press protrusions 84 penetrates into the first bonding portion 40, and a thick portion around the opening of each of the initial recessed portions 82 is inserted thereinto to protrude from the inner surface of the initial recessed portion 82 to the center side.

When the second die 83 is pressed up to a predetermined depth, the inclined surfaces 72 and the flange portion 73 (refer to FIG. 9) are formed by the thick portions protruding to the center side of the initial recessed portions 82. This way, the first roughened recessed portions 49a including the peeling suppressing portion 70 can be formed by the two-stage pressing using the first die 80 and the second die 83.

In a case where the first roughened recessed portions 49a are formed by the two-stage pressing as described above, when the metal wiring board 4 is large and the number of locations (number of the first roughened recessed portions 49a) on which the two-stage pressing is to be performed is large, a load on a press machine increases, and it is difficult to manufacture the first roughened recessed portions 49a with a small and low-power press machine. In addition, when the interval of the plurality of first roughened recessed portions 49a is narrow, it is difficult to form the first roughened recessed portions 49a having a good shape with high accuracy due to the influence of displacement or the like of the first die 80 and the second die 83 relative to the first bonding portion 40. In addition, when the interval of the plurality of first roughened recessed portions 49a is narrow and the number of the plurality of first roughened recessed portions 49a is large, deformation or distortion of the metal wiring board 4 is likely to occur even at a location other than the first roughened recessed portions 49a due to the influence or the like of the load applied during manufacturing.

On the other hand, when the interval of the plurality of first roughened recessed portions 49a is increased, a smooth portion on the upper surface of the first bonding portion 40 is widened, and the peeling of the sealing resin 5 in the smooth portion is likely to progress.

In consideration of the above-described various conditions, as illustrated in FIGS. 10 to 13, a structure where the first roughened recessed portions 49a including the peeling suppressing portion 70 and the second roughened recessed portions 49b not including the peeling suppressing portion 70 are combined can also be selected.

The second embodiment illustrated in FIG. 10 is a configuration example where the first roughened recessed portions 49a including the peeling suppressing portion 70 are arranged on only one array on the outermost periphery of the upper surface of the first bonding portion 40 and the second roughened recessed portions 49b not including the peeling suppressing portion 70 are arranged inside of the first roughened recessed portions 49a. The second roughened recessed portion 49b is a recessed portion having a square pillar shape that includes a bottom surface 75 having a rectangular shape in plan view and four substantially parallel side surfaces 76 extending upward from four sides of the bottom surface 75, and an upper end portion of each of the side surfaces 76 is opened to the upper surface of the first bonding portion 40 (refer to FIG. 5).

With the configuration of FIG. 10, by arranging the first roughened recessed portions 49a having a structure where the adhesion with the sealing resin 5 is high on the outer peripheral side of the first bonding portion 40 where peeling is most likely to occur, at least the formation locations of the first roughened recessed portions 49a can effectively improve the effect of suppressing the peeling of the sealing resin 5. In addition, the regions of the upper surface of the first bonding portion 40 other than the outer peripheral side are roughened by the second roughened recessed portions 49b that can be easily manufactured and have a simple structure where deformation or distortion of the metal wiring board 4 is not likely to occur, and the effect of suppressing the peeling of the sealing resin 5 can be obtained using the plurality of second roughened recessed portions 49b.

In the third embodiment illustrated in FIG. 11, the first roughened recessed portions 49a including the peeling suppressing portion 70 are arranged on two arrays positioned outside of the through holes 46 present in the non-roughened region on the upper surface of the first bonding portion 40, and the second roughened recessed portions 49b not including the peeling suppressing portion 70 are arranged inside of the first roughened recessed portions 49a.

As in the configuration of FIG. 11, by arranging the first roughened recessed portions 49a having high adhesion with the sealing resin 5 in all of the regions closer to the end surface (outer side) of the metal wiring board 4 than the through holes 46 in the non-roughened region, the peeling of the sealing resin 5 can be easily prevented from progressing up to the non-roughened region. In addition, the region inside of the through holes 46 is roughened by the second roughened recessed portions 49b that can be easily manufactured and have a simple structure where deformation or distortion of the metal wiring board 4 is not likely to occur, and the effect of suppressing the peeling of the sealing resin 5 can be obtained using the plurality of second roughened recessed portions 49b.

On the upper surface of the first bonding portion 40, the first roughened recessed portions 49a including the peeling suppressing portion 70 may be intermittently arranged between the second roughened recessed portions 49b not including the peeling suppressing portion 70. For example, as in the arrangement of the roughened recessed portions 49 in the X direction of FIG. 4, due to the intermittent arrangement where, for example, two first roughened recessed portions 49a, one second roughened recessed portion 49b, and two first roughened recessed portions 49a are arranged, deformation or distortion of the metal wiring board 4 can be suppressed.

The fourth embodiment illustrated in FIG. 12 is an example where the first roughened recessed portion 49a and the second roughened recessed portion 49b are alternately arranged as the intermittent arrangement of the first roughened recessed portions 49a and the second roughened recessed portions 49b. The first roughened recessed portion 49a is arranged at one corner portion of the first bonding portion 40, the second roughened recessed portion 49b is arranged at positions adjacent to the first roughened recessed portion 49a in the X direction and the Y direction, and the first roughened recessed portion 49a is arranged again at positions adjacent thereto in the X direction and the Y direction. This way, by alternately arranging the first roughened recessed portion 49a and the second roughened recessed portion 49b, the first roughened recessed portions 49a that are formed by the two-stage pressing are alternately and intermittently arranged. As a result, the first roughened recessed portions 49a can be easily manufactured over the entire first bonding portion 40, and deformation or distortion of the metal wiring board 4 is not likely to occur.

In the fifth embodiment illustrated in FIG. 13, the first roughened recessed portion 49a including the peeling suppressing portion 70 and the second roughened recessed portion 49b not including the peeling suppressing portion 70 are alternately arranged (the first roughened recessed portions 49a are intermittently arranged) in the region outside of the through holes 46 present in the non-roughened region on the upper surface of the first bonding portion 40. That is, the same configuration as that of FIG. 10 is adopted in the region inside of the through holes 46 (non-roughened region), and the same configuration as that of FIG. 12 is adopted in the region outside of the through holes 46 (non-roughened region).

In FIGS. 4, 8, 10, 11, 12, and 13, the first roughened recessed portions 49a or the second roughened recessed portions 49b are arranged in a rectangular lattice shape. However, the first roughened recessed portions 49a or the second roughened recessed portions 49b may be arranged in a staggered manner.

The above-described peeling suppressing portion 70 includes the flange portion 73 having a shape that is continuous along the entire circumference of the inner surface of the first roughened recessed portion 49a in plan view. In one first roughened recessed portion, a plurality of peeling suppressing portions that are arranged to be dispersed in plan view may be provided.

In addition, the above-described first roughened recessed portions 49a are formed by the two-stage pressing using the first die 80 and the second die 83. However, the roughened recessed portions including the peeling suppressing portion can also be formed by three or more stages of pressing. In this case, the peeling suppressing portion formed in the roughened recessed portion is different from the peeling suppressing portion 70 of the first roughened recessed portion 49a and is likely to include plural stages of flange portions.

In addition, the above-described first roughened recessed portion 49a includes the open recessed portion 74 having a square pillar shape on the upper side of the flange portion 73, and includes the space surrounded by the four inclined surfaces 72 and the bottom surface 71 on the lower side of the flange portion 73. However, the shape of the roughened recessed portion including the peeling suppressing portion is not limited to this example. For example, the basic shape of the roughened recessed portion may be a columnar shape or a semispherical shape, and the peeling suppressing portion may be formed as a portion that protrudes to the inner surface thereof.

Also, in the above-described embodiment, the first bonding portion 40 of the metal wiring board 4 includes the through holes 46 in the non-roughened region of the upper surface. However, the configuration of the non-roughened region is not limited to the through holes. For example, when a wire is connected to the upper surface of the metal wiring board 4, a location to which the wire is to be connected may be the non-roughened region. In addition, a protrusion portion that protrudes upward from the metal wiring board 4, a bottomed hole (recessed portion having a shape, a depth, or the like different from that of the roughened recessed portion) that is provided on the upper surface of the metal wiring board 4, or the like can also be applied as the non-roughened region.

In addition, the present invention is also applicable to the bonding portion of the metal wiring board that does not include the non-roughened region such as the through holes 46 on the upper surface (where the plurality of roughened recessed portions are arranged on the entire area).

As described above, with the present embodiment, the adhesion between the metal wiring board and the sealing resin can be improved. In addition, according to the present invention, it is possible to improve the bonding strength between the semiconductor element and the metal wiring board while securing the thickness of the bonding material.

Although the present embodiment and the modification examples have been described above, the above-described embodiment and modification examples may be wholly or partially combined as another embodiment.

In the above-described embodiment, the number and arrangement location of the semiconductor element are not limited to the above-described configuration, and can appropriately be changed.

Furthermore, in the above-described embodiment, the number and layout of the circuit board are not limited to the above-described configuration, and can be changed as appropriate.

In the above-described embodiment, the stacked substrate or the semiconductor element has a rectangular shape or a square shape in a planar view, but the present invention is not limited to this configuration. These components may each have a polygonal shape other than the above-described shape.

In addition, the present embodiment is not limited to the above-described embodiment and modification examples, and various changes, substitutions, and modifications may be made without departing from the spirit of the technical idea. Further, when the technical idea can be realized in another manner by the progress of the technology or another derived technology, the technical idea may be carried out by using a method thereof. Accordingly, the claims cover all implementations that may be included within the scope of the technical idea.

Feature points in the embodiment described above will be summarized below.

The semiconductor module according to the above-described embodiment includes: a stacked substrate in which a plurality of circuit boards are arranged on an upper surface of an insulating plate; a semiconductor element arranged on an upper surface of at least one of the circuit boards; and a metal wiring board arranged on an upper surface of the semiconductor element, in which the metal wiring board has a bonding portion bonded to the upper surface of the semiconductor element via a bonding material, the bonding portion includes a plate-shaped portion having an upper surface and a lower surface, the plate-shaped portion includes a plurality of roughened recessed portions that roughen the upper surface, and at least some of the plurality of roughened recessed portions include a peeling suppressing portion that protrudes inward and narrows an open width.

In addition, a non-roughened region not including the roughened recessed portions is provided on the upper surface of the plate-shaped portion, the plurality of roughened recessed portion includes a first roughened recessed portion including the peeling suppressing portion and a second roughened recessed portion not including the peeling suppressing portion, the first roughened recessed portion is arranged outside of the non-roughened region in the bonding portion, and the second roughened recessed portion is arranged inside of the non-roughened region in the bonding portion.

In addition, the non-roughened region includes a through hole penetrating the plate-shaped portion.

In addition, the plurality of roughened recessed portions include a first roughened recessed portion including the peeling suppressing portion and a second roughened recessed portion not including the peeling suppressing portion, and the first roughened recessed portion is intermittently arranged between the second roughened recessed portions.

In addition, a method for manufacturing the semiconductor module according to the above-described embodiment includes forming the roughened recessed portion including the peeling suppressing portion by performing pressing multiple times.

### INDUSTRIAL APPLICABILITY

As described above, the present invention has an effect of improving the adhesion between the bonding portion of the metal wiring board and the sealing resin and is particularly useful for a semiconductor module for industrial or electrical equipment and a method for manufacturing the semiconductor module.

The present application is based on Japanese Patent Application No. 2022-177078 filed on Nov. 4, 2022. All the contents are included herein.

### REFERENCE SIGNS LIST

1 Semiconductor module
2 Stacked substrate
3 Semiconductor element
4 Metal wiring board
5 Sealing resin
10 Cooler
11 Case
20 Insulating plate
21 Heat dissipation plate
22 Circuit board
40 First bonding portion (bonding portion)
41 Second bonding portion
42 Connecting portion
43 First bent portion
44 Second bent portion
46 Through hole (non-roughened region)
48 Through hole
49 Roughened recessed portion
49a First roughened recessed portion (roughened recessed portion including peeling suppressing portion)
49b Second roughened recessed portion (roughened recessed portion not including peeling suppressing portion)
60 Main terminal
61 Control terminal
70 Peeling suppressing portion
71 Bottom surface
72 Inclined surface
73 Flange portion
74 Open recessed portion
75 Bottom surface
76 Side surface
80 First die
83 Second die
100 Semiconductor device
F Coating film
S1 Bonding material
S2 Bonding material
S3 Bonding material
S4 Bonding material

1. A semiconductor module comprising:
a stacked substrate, which includes:
an insulating plate, and
a plurality of circuit boards formed on an upper surface of the insulating plate;
a semiconductor element formed on an upper surface of one of the plurality of circuit boards; and
a metal wiring board formed on an upper surface of the semiconductor element, wherein
the metal wiring board has a bonding portion bonded to the upper surface of the semiconductor element via a bonding material,
the bonding portion includes a plate-shaped portion having an upper surface and a lower surface,
the plate-shaped portion has a roughened region in which a plurality of recessed portions are formed on the upper surface of the plate-shaped portion, and
the plurality of recessed portions include a plurality of first recessed portions that each has a peeling suppressing portion protruding inward to thereby narrow a width of said each first recessed portion.

2. The semiconductor module according to claim 1, wherein
the plate-shaped portion further has a non-roughened region in which the upper surface of the plate-shaped portion is substantially flat,
the plurality of recessed portions further includes a plurality of second recessed portions, each of which is free of the peeling suppressing portion, and
the plurality of first recessed portions is arranged outside of the non-roughened region in the bonding portion.

3. The semiconductor module according to claim 2, wherein the plate-shaped portion has, in the non-roughened region, a through hole penetrating through the plate-shaped portion.

4. The semiconductor module according to claim 1, wherein
the plurality of recessed portions further includes a plurality of second recessed portion, each of which is free of the peeling suppressing portion, and
the plurality of first recessed portions is intermittently arranged among the plurality of second recessed portions.

5. A method for manufacturing the semiconductor module according to claim 1, the method comprising forming the plurality of first recessed portions by performing pressing multiple times.
